(19) United States
(12) Patent Application Publication
(10) Pub. No.: US 2025/0216487 A1
(43) Pub. Date: Jul. 3, 2025

(54) GRADIENT COIL ASSEMBLY AND MAGNETIC RESONANCE IMAGING SYSTEM

(71) Applicants: SHANGHAI UNITED IMAGING HEALTHCARE CO., LTD., Shanghai (CN); ZHEJIANG UNIVERSITY, Hangzhou (CN)

(72) Inventors: Jiwen YANG, Shanghai (CN); Shuguang LIU, Shanghai (CN); Man FAN, Shanghai (CN); Changlin SHEN, Shanghai (CN); Lifeng WANG, Shanghai (CN); Yuan GAO, Shanghai (CN); Dan WU, Hangzhou (CN); Liyi KANG, Hangzhou (CN)

(73) Assignees: SHANGHAI UNITED IMAGING HEALTHCARE CO., LTD., Shanghai (CN); ZHEJIANG UNIVERSITY, Hangzhou (CN)

(21) Appl. No.: 19/004,347

(22) Filed: Dec. 29, 2024

(30) Foreign Application Priority Data
Dec. 29, 2023 (CN) 202311868364.7
Dec. 29, 2023 (CN) 202323664830.8

(51) Int. Cl. G01R 33/385; G01R 33/421

(52) U.S. Cl. CPC G01R 33/385; G01R 33/421

(57) ABSTRACT

A gradient coil assembly and a magnetic resonance imaging system comprising a Z-axis gradient coil are provided. The gradient coil assembly comprises a Z-axis gradient coil. The Z-axis gradient coil comprising a first coil and a second coil, the first coil and the second coil being arranged along an axial direction of the Z-axis gradient coil. The first coil comprises a first subcoil and a second subcoil. The first subcoil and the second subcoil extend alongside each other. The second coil comprises a third subcoil and a fourth subcoil. The third subcoil and the fourth subcoil extend alongside each other.

### CROSS-REFERENCE TO RELATED APPLICATIONS

This application claims priority to Chinese application No. 202323664830.8, filed Dec. 29, 2023, and Chinese application No. 202311868364.7, filed Dec. 29, 2023, the entire contents of each of which are incorporated herein by reference.

### TECHNICAL FIELD

The present disclosure relates to the technical field of magnetic resonance devices, and in particular, to a gradient coil assembly and a magnetic resonance imaging system.

### BACKGROUND

A Z-axis gradient coil is an essential component of a magnetic resonance imaging system, responsible for generating a gradient magnetic field along a Z direction. Typically, each magnetic field strength corresponds uniquely to a specific position along the Z-axis, allowing image coordinates to be accurately calibrated using the linear magnetic field of the Z-axis gradient coil. However, beyond an inflection point of the gradient magnetic field of the Z-axis gradient coil, a single magnetic field strength may correspond to multiple positions along the Z-axis. This overlap can result in simultaneous imaging of two separate regions, leading to artifacts in a magnetic resonance imaging image.

In the related art, a single winding path is typically employed to wind conductors of the Z-axis gradient coil. This approach results in a sparser distribution of the conductors and a concentrated current. The close inflection point to an origin in the generated gradient magnetic field can lead to the simultaneous imaging of multiple regions. This overlap interferes with original image signals, producing artifacts and reducing the accuracy of the magnetic resonance imaging image.

Furthermore, existing gradient coils often employ a whole-body symmetric gradient coil, where diameters of the gradient coils remain the same throughout the length of a human body. However, when a magnetic resonance imaging device needs to perform a targeted scan of the human head, the relatively small size of the human head necessitates increased gradient coil strength at the scanning site. The whole-body symmetric gradient coil is typically inadequate for such specific requirements. Additionally, due to wide areas such as the shoulders, narrowing the gradient coil can hinder easy access for the human body.

Therefore, it is desired to provide a gradient coil assembly and a magnetic resonance imaging system that can effectively enhance the gradient coil performance and improve the quality of imaging while meeting the requirements of targeted scan.

### SUMMARY

One or more embodiments of the present disclosure provide a gradient coil assembly comprises a Z-axis gradient coil. The Z-axis gradient coil comprises a first coil and a second coil. The first coil and the second coil are arranged along an axial direction of the Z-axis gradient coil. The first coil comprises a first subcoil and a second subcoil, the first subcoil and the second subcoil extend alongside each other. The second coil comprises a third subcoil and a fourth subcoil, the third subcoil and the fourth subcoil extend alongside each other. The third subcoil is connected in series with the first subcoil to be supplied with a first current, the fourth subcoil is connected in series with the second subcoil to be supplied with a second current.

One or more embodiments of the present disclosure provide a magnetic resonance imaging system comprises a gradient coil assembly, the gradient coil assembly comprises a Z-axis gradient coil, the Z-axis gradient coil comprises a first coil and a second coil, the first coil and the second coil being arranged along an axial direction of the Z-axis gradient coil. The first coil comprises a first subcoil and a second subcoil, the first subcoil and the second subcoil extend alongside each other. The second coil comprises a third subcoil and a fourth subcoil, the third subcoil and the fourth subcoil extend alongside each other. The third subcoil is connected in series with the first subcoil to be supplied with a first current, the fourth subcoil is connected in series with the second subcoil to be supplied with a second current.

### BRIEF DESCRIPTION OF THE DRAWINGS

The present disclosure will be further illustrated by way of exemplary embodiments, which will be described in detail by means of the accompanying drawings. These embodiments are not limiting, and in these embodiments, the same numbering denotes the same structure, where:

FIG. 1 is a schematic diagram of a conductor structure of a Z-axis gradient coil according to some embodiments of the present disclosure;

FIG. 2 is a schematic diagram of a structure of a Z-axis gradient coil with a shielding coil according to some embodiments of the present disclosure;

FIG. 3 is a schematic diagram of a structure of a Z-axis gradient coil according to some embodiments of the present disclosure;

FIG. 4 is a schematic diagram of a structure of a gradient coil assembly in the related art;

FIG. 5 is a schematic illustration of a distribution of RF imageable region shown according to some embodiments of the present disclosure;

FIG. 6 is a schematic diagram of a portion of a structure of a gradient coil assembly according to some embodiments of the present disclosure;

FIG. 7 is a schematic diagram of a portion of a structure of a gradient coil assembly according to some embodiments of the present disclosure;

FIG. 8 is a schematic diagram of a structure of a first coil according to some embodiments of the present disclosure;

FIG. 9 is a schematic diagram of a structure of a second coil according to some embodiments of the present disclosure;

FIG. 10 is a cross-sectional view of a magnetic resonance apparatus according to some embodiments of the present disclosure;

FIG. 11 is a cross-sectional view of a magnetic resonance apparatus according to some embodiments of the present disclosure;

FIG. 12 is a cross-sectional view of a gradient coil assembly according to some embodiments of the present disclosure;

FIG. 13 is another angled cross-sectional view of a gradient coil assembly according to some embodiments of the present disclosure;

FIG. 14 is a schematic diagram of a magnetic resonance apparatus according to some embodiments of the present disclosure;

FIG. 15 is a schematic diagram of a distribution of a magnetic field formed by an X-axis coil according to some embodiments of the present disclosure;

FIG. 16 is a linearity distribution of an X-axis coil on an XZ plane according to some embodiments of the present disclosure;

FIG. 17 is a schematic diagram of a distribution of a magnetic field formed by a Y-axis coil according to some embodiments of the present disclosure; and

FIG. 18 is a linearity distribution of a Y-axis coil on a YZ plane according to some embodiments of the present disclosure.

### DETAILED DESCRIPTION

In order to more clearly illustrate the technical solutions of the embodiments of the present disclosure, the accompanying drawings required to be used in the description of the embodiments are briefly described below. Obviously, the accompanying drawings in the following description are only some examples or embodiments of the present disclosure, and it is possible for a person of ordinary skill in the art to apply the present disclosure to other similar scenarios in accordance with these drawings without creative labor. Unless obviously obtained from the context or the context illustrates otherwise, the same numeral in the drawings refers to the same structure or operation.

It should be understood that the terms “system,” “device,” “unit,” and/or “module” as used herein is a way to distinguish between different components, elements, parts, sections or assemblies at different levels. However, the words may be replaced by other expressions if other words accomplish the same purpose.

Unless the context clearly suggests an exception, the words “one,” “a,” “one,” “a,” and/or “the” do not refer specifically to the singular, but may also include the plural. Generally, the terms “including,” and “comprising” suggest only the inclusion of clearly identified steps and elements. In general, the terms “including,” and “comprising” only suggest the inclusion of explicitly identified steps and elements that do not constitute an exclusive list, and the method or apparatus may also include other steps or elements.

During a magnetic resonance imaging process, a linear magnetic field of a gradient coil is utilized to calibrate coordinates of an image, which can be expressed as:

$${B}_{z} = {G}_{x} x + {G}_{y} y + {G}_{z} z$$

where B_{z} denotes a gradient magnetic field at a certain position, Gₓ, G_{y}, and G_{z} denote gradient strengths of the gradient coil on the X-axis, Y-axis, and Z-axis, respectively, and (x, y, z) denotes imaging coordinates on the X-axis, Y-axis, and Z-axis, respectively. For ease of expression, only the magnetic field of the Z-axis gradient coil is considered here. Thus, the gradient magnetic field at a certain position is expressed as:

B_{z}=G_{z}z

Usually, the magnetic field of a Z-axis gradient coil increases monotonically along the Z coordinate. For example, each gradient magnetic field Bz corresponds to a Z coordinate. If the magnetic field of the Z-axis gradient coil is no longer monotonically increasing along the Z coordinate from a certain Z coordinate, one gradient magnetic field Bz may correspond to two Z coordinates, which may lead to simultaneous imaging of two regions, and hence producing artifacts.

In order to solve the above problem, some embodiments of the present disclosure provide a gradient coil assembly comprises a Z-axis gradient coil. The Z-axis gradient coil comprises a first coil and a second coil. The first coil and the second coil are arranged along an axial direction of the Z-axis gradient coil. The first coil comprises a first subcoil and a second subcoil. The first subcoil and the second subcoil extend alongside each other. The second coil comprises a third subcoil and a fourth subcoil. The third subcoil and the fourth subcoil extend alongside each other. The third subcoil is connected in series with the first subcoil to be supplied with a first current. The fourth subcoil is connected in series with the second subcoil to be supplied with a second current. The first current is connected in parallel with the second current. A direction of the first current is the same as a direction of the second current.

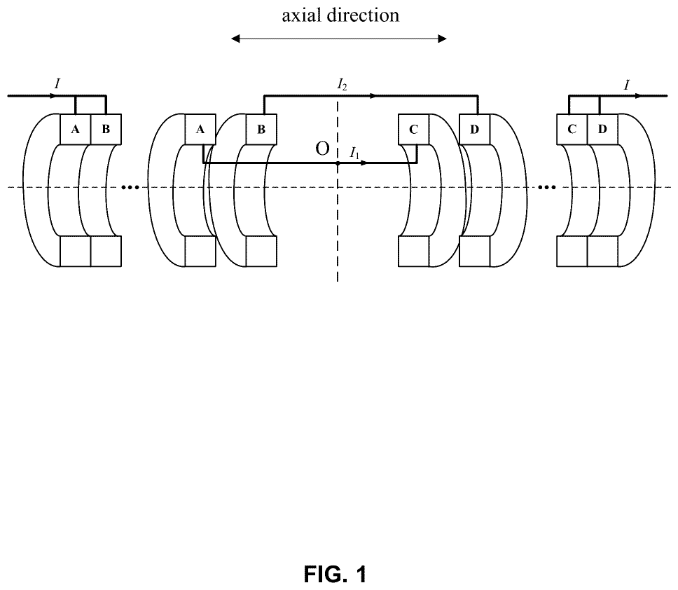

FIG. 1 is a schematic diagram of a conductor structure of a Z-axis gradient coil according to some embodiments of the present disclosure. As shown in FIG. 1, the first coil includes a first subcoil A and a second subcoil B. The first subcoil A and the second subcoil B are disposed side-by-side in an axial direction. The second coil includes a third subcoil C and a fourth subcoil D. The third subcoil C and the fourth subcoil D are provided side-by-side in the axial direction.

In some embodiments, after a current is passed through the each first coil or the each second coil, the current forms two branches including a first spiral winding and a second spiral winding. The first spiral winding is a current branch I1 formed by connecting the first subcoil A in series with the third subcoil C, and the second spiral winding is a current branch I2 formed by connecting the second subcoil B in series with the fourth subcoil D. The first spiral winding is connected in parallel with the second spiral winding. Understandably, a direction of the current in FIG. 1 is only an example, and it is possible that the actual direction of the current is the opposite (e.g., from right to left) of that in FIG. 1.

In some embodiments, the first subcoil A, the second subcoil B, the third subcoil C, and the fourth subcoil D are wound at a same coil radius and the first coil is symmetric with the second coil about a center of the gradient coil.

In some embodiments, the X-axis gradient coil, the Y-axis gradient coil may also comprise a first coil and a second coil arranged in the axial direction, and the manner of connecting and the structure of the coils of the X-axis gradient coil or the Y-axis gradient coil may be similar to that of the first coil and the second coil in the Z-axis gradient coil. Please refer to the relevant descriptions in the preceding section, and at the same time, the description of the connection method or structure of the first coil and the second coil in the Z-axis gradient coil in the latter section can be similarly applied to the X-axis gradient coil and the Y-axis gradient coil.

In some embodiments, the first coil of the Z-axis gradient coil may further comprise a fifth subcoil. The fifth subcoil is arranged in an axial direction along the Z-axis gradient coil with the first subcoil and the second subcoil. The second coil comprises a sixth subcoil. The sixth subcoil is arranged axially along the Z-axis gradient coil with the third subcoil and the fourth subcoil. The sixth subcoil is connected in series with the fifth subcoil to form a third spiral winding. The first spiral winding, the second spiral winding, and the third spiral winding are connected in parallel. In some embodiments, the first coil and the second coil of the Z-axis gradient coil may also include more similarly arranged subcoils, which may be designed according to actual needs.

The magnetic field is generated by means of a gradient coil assembly comprising a first coil and a second coil wound symmetrically about the center of the gradient coil. The first coil comprises a first subcoil and a second subcoil connected in parallel. The second coil comprises a third subcoil and a fourth subcoil. The third subcoil is connected in series with the first subcoil, and the fourth subcoil is connected in series with the second subcoil, so as to ensure that under a circumstance that a strength of the gradient magnetic field in an imaging area remains constant, the subcoil is winded by two branches. A distribution area of the current under the circumstance of unchanged strength of the magnetic field is increased, and at the same time the strength of the current of each branch is reduced, thus the inflection point of the gradient magnetic field is far from the origin, the imaging area is wide, and it is not easy to generate artifacts during the imaging process. Thus, the problem of low accuracy in the related technology is solved and the imaging accuracy is improved.

In some embodiments, the first subcoil is connected to the second subcoil at an end of the Z-axis gradient coil. As the first subcoil and the second subcoil located at the ends of the Z-axis gradient coils are joined, the current branch is formed by the first subcoils and the third subcoil, and the current branch is formed by the second subcoil and the fourth subcoil. The two current branches are connected in parallel.

At the end of the Z-axis gradient coil, the first subcoil A is joined with the second subcoil B, as shown in FIG. 1. A joining method may be a weld, a crimp, or any other joining method that can connect the first subcoil A with the second subcoil B.

By joining the first subcoil A and the second subcoil B at the end of the Z-axis gradient coil, a parallel connection relationship between the first subcoil A and the second subcoil B is guaranteed, so that the current passed through may form two branches in the first subcoil A and the second subcoil B respectively, thereby increasing a current distribution area under a same magnetic field strength. At the same time, since the two branches share the current, the current of each branch is reduced, thus making the magnetic field have a inflection point far away from the origin at the corresponding coordinates and artifacts are reduced.

In some embodiments, the third subcoil is connected to the fourth subcoil at another end of the Z-axis gradient coil.

At the end of the Z-axis gradient coil, the third subcoil C is joined with the fourth subcoil D as shown in FIG. 1. The joining method may be a weld, a crimp, or other joining method that can connect the third subcoil C with the fourth subcoil D.

By joining the first subcoil A and the second subcoil B at the end of the Z-axis gradient coil, the parallel connection relationship between the first subcoil A and the second subcoil B is guaranteed, so that the current passed through may form two branches in the first subcoil A and the second subcoil B respectively, thereby increasing the current distribution area under the same magnetic field strength. At the same time, since the two branches share the current, the current of each branch is reduced, thus making the magnetic field have a inflection point far away from the origin at the corresponding coordinates and the artifacts are reduced.

In some embodiments, the first subcoil is connected to the third subcoil near the center of the Z-axis gradient coil. It should be noted that the first subcoil near the center of the Z-axis gradient coil is considered to be the first subcoil of the plurality of first subcoils that is closest to the center of the Z-axis gradient coil.

As shown in FIG. 1, at the center O of the Z-axis gradient coil (e.g., at the end of the first coil and at a first section of the second coil), the first subcoil A is joined to the third subcoil C. The joining method may be a weld, a crimp, or other joining method that can join the first subcoil A to the third subcoil C.

By joining the first subcoil A and the third subcoil C at the center of the coil, a series relationship between the first subcoil A and the third subcoil C is ensured, thereby enabling the current passes from the first subcoil A to form a branch circuit on the first subcoil A and the third subcoil C, and enlarging the area of distribution of the current while the magnetic field strength remains constant.

In some embodiments, the second subcoil is connected to the fourth subcoil near the center of the Z-axis gradient coil. It should be noted that the second subcoil near the center of the Z-axis gradient coil is considered to be the second subcoil of the plurality of second subcoils that is closest to the center of the Z-axis gradient coil.

As shown in FIG. 1, at the center of the Z-axis gradient coil (e.g., at the end of the first coil and at a first section of the second coil), the second subcoil B is joined to the fourth subcoil D. The joining method may be a weld, a crimp, or other joining method that can join the second subcoil B to the fourth subcoil D.

By joining the second subcoil B at the center of the coil with the fourth subcoil D, a series relationship between the second subcoil B and the fourth subcoil D is ensured, so that the current passes from the second subcoil B may form a branch circuit on the second subcoil B and the fourth subcoil D, thereby enlarging the distribution area of the current while the magnetic field strength remains constant.

In some embodiments, winding trajectories of the first subcoil and the fourth subcoil are centrally symmetric about the center of the Z-axis gradient coil.

As shown in FIG. 1, the first subcoil A and the fourth subcoil D are symmetrically disposed on both sides of the Z-axis gradient coil, and the winding trajectories of the first subcoil A and the fourth subcoil D are centrally symmetric about the center of the Z-axis gradient coil.

By symmetrically winding the first subcoil A and the fourth subcoil D about the center of the Z-axis gradient coil utilizing a same winding trajectory, the magnetic field generated by energizing the first subcoil A and the fourth subcoil D is centrosymmetric and does not affect normal operations of the magnetic resonance imaging system.

In some embodiments, the winding trajectories of the second subcoil and the third subcoil are centrally symmetric about the center of the gradient coil assembly.

As shown in FIG. 1, the second subcoil B and the third subcoil C are symmetrically disposed on both sides of the gradient coil, and the winding trajectories of the second subcoil B and the third subcoil C are centrally symmetric about the center of the gradient coil assembly.

By symmetrically winding the second subcoil B and the third subcoil C, using a same winding trajectory about the center of the gradient coil assembly, the magnetic field generated by energizing the second subcoil B and the third subcoil C is about the center of the gradient coil assembly in a centrosymmetric and does not affect the normal operations of the magnetic resonance imaging system.

In some embodiments, since the winding trajectories are the same and centrally symmetric, load parameters of the two branches are the same. The load parameters include a resistance and an inductance of each of the two branches, so as to realize the same current in real time in each branch, and thus realize the symmetrical distribution of the magnetic field generated by the symmetrically distributed coils. Thus, normal working conditions of the magnetic resonance imaging system are ensured.

In some embodiments, the gradient coil assembly includes a main coil and a shielding coil. The shielding coil is arranged around the outside, in a radial direction, of the main coil. In some embodiments, the Z-axis gradient coil may be the main coil, or at least a portion of the main coil. In some embodiments, the Z-axis gradient coil may be a shielding coil, or at least a portion of a shielding coil.

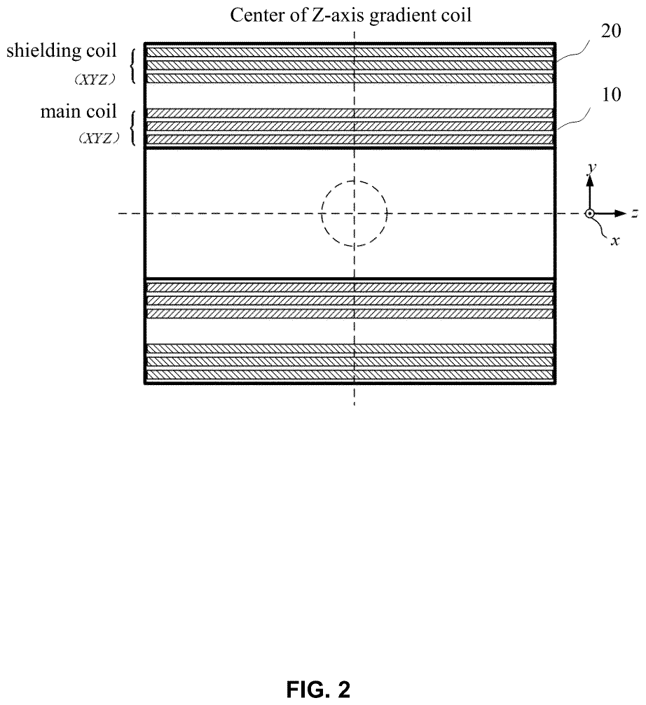

FIG. 2 is a schematic diagram of a structure of a Z-axis gradient coil with a shielding coil according to some embodiments of the present disclosure. As shown in FIG. 2, the Z-axis gradient coil comprising the first coil and the second coil serves as a main coil 10, a shielding coil 20 is arranged around the outside, in a radial direction, of the main coil 10. An axis of the main coil 10 and an axis of the shielding coil 20 coincide to ensure an uniformity of the magnetic field and thus improving the imaging quality.

In some embodiments, both the main coil 10 and the shielding coil 20 are formed by winding coils in the X, Y, and Z directions. Thus, magnetic fields in the X, Y, and Z directions are generated.

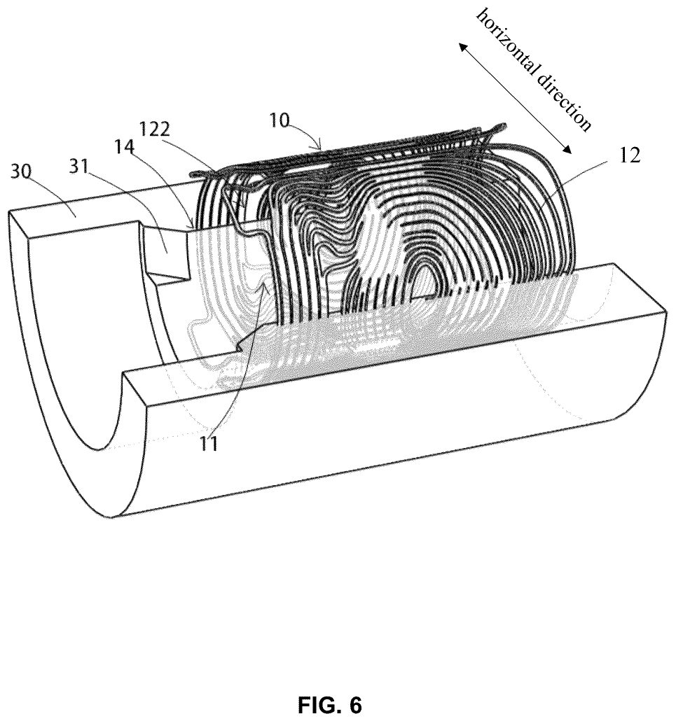

The shielding coil 20 is configured to generate a gradient shielding magnetic field to avoid the magnetic field generated by the main coil 10 from interfering with the magnetic field generated by other coils of the magnetic resonance imaging system, so as to ensure normal and stable working conditions of the magnetic resonance imaging system. More related content about the main coil and the shielding coil may be found in FIG. 6-FIG. 9 and their related descriptions.

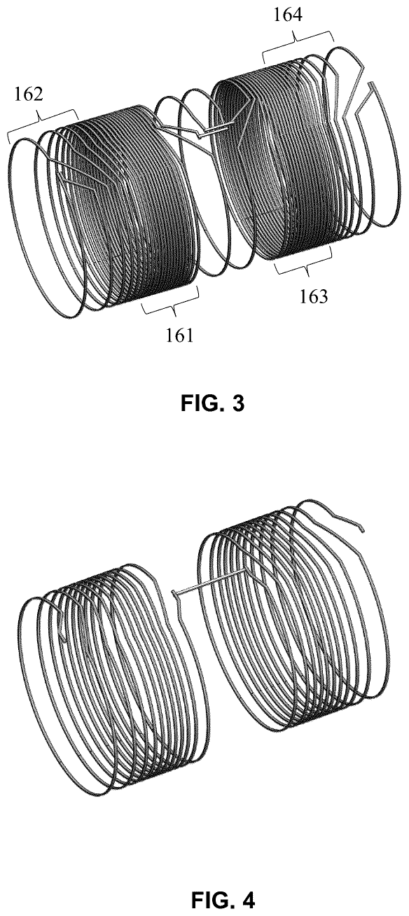

In some embodiments, FIG. 3 is a schematic diagram of the structure of a Z-axis gradient coil according to some embodiments of the present disclosure. FIG. 4 is a schematic diagram of a structure of a gradient coil assembly in the related art. As shown in FIG. 3, the Z-axis gradient coil is wound with two branches of subcoils. Compared to the Z-axis gradient coil of the related art in FIG. 4, the Z-axis gradient coil of the embodiment of the present disclosure has a larger current distribution area and the magnetic field distribution has a more distant inflection point from the origin.

Exemplarily, a location of the inflection point of the magnetic field distribution of the Z-axis gradient coil in FIG. 3 is Z=0.38 m, and a location of the inflection point of the magnetic field distribution of the Z-axis gradient coil in the related technology is Z=0.33 m.

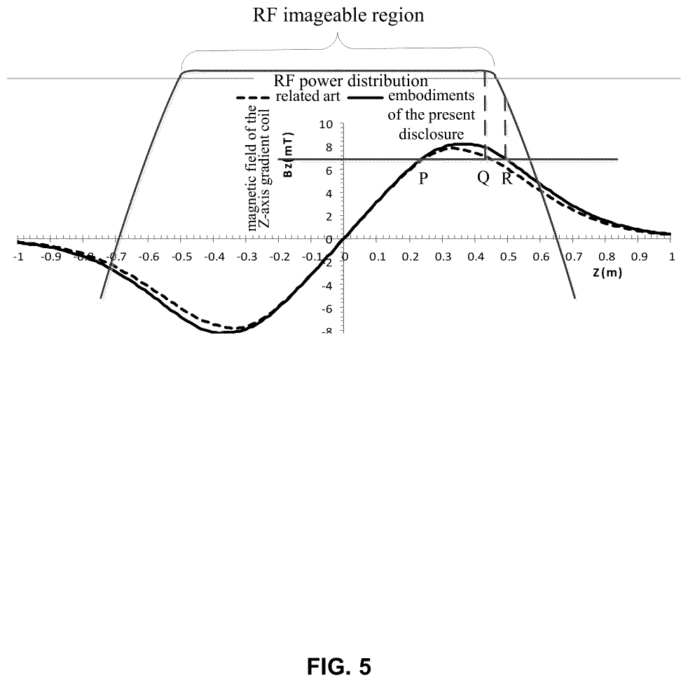

FIG. 5 is a schematic diagram of a distribution of RF imageable region according to some embodiments of the present disclosure. As shown in FIG. 5, the magnetic field strength of the Z-axis gradient coil in the related art is represented by a dashed line, and the Z-axis gradient coil magnetic field strength according to the embodiments of the present disclosure is represented by a solid line. As shown in FIG. 5, imaging positions at a determined magnetic field strength of the Z-axis gradient coil in the related art are represented by points P and Q on the dashed line. And imaging positions at the same determined magnetic field strength of the Z-axis gradient coil according to the embodiments of the present disclosure are represented by points P and R on the solid line. For the related art, since both points P and Q are within the RF imageable region shown in FIG. 5, both points P and Q may be imaged, thereby producing a roll fold artifact. For the embodiments of the present disclosure, on the other hand, since only point P is within the RF imageable region, only point P may be imaged and therefore no artifacts is produced.

As shown in FIG. 5, a furthest RF imageable region is Z=0.45 m. That is, RF intensities in regions within Z<0.45 m are all likely to generate image signals. During an imaging process, when the gradient strength is 30 mT/m, and the magnetic field strength corresponding to an RF receiving frequency is B0+7.2 mT (Bz=γf, where Bz is the magnetic field strength, γ is the magnetic spin ratio, the magnetic spin ratio is 42.58 MHz/T for hydrogen atoms, and f is the RF receiving frequency), an imaging location is Z=0.24 m, and the Z-axis gradient coil magnetic field at the imaging location is 7.2 mT.

For the gradient coil in the related technology, the magnetic field of the Z-axis gradient coil at Z=0.43 m is also 7.2 mT. However, different from the embodiments of the present disclosure, the location Z=0.43 m is located in the RF imageable region (Z<0.45 m) in the related technology, so in the related technology, tissues and organs at this location generate signals that interfere with original image signals, thus generating artifacts. For the gradient coil in this embodiment, the magnetic field of the Z-axis gradient coil at Z=0.5 m is also 7.2 mT, but at this time, the location is no longer in the RF imageable region (Z<0.45 m), so that the tissues and organs at this location do not generate signals, and therefore no artifacts are be generated, thus avoiding artifacts during the imaging process, and improving the accuracy of the magnetic resonance imaging image.

In some embodiments, along the axial direction of the Z-axis gradient coil, the first coil has different densities of continuous helical wrapping and the second coil has different densities of continuous helical wrapping.

In some embodiments, the closer to the center of the Z-axis gradient coil along the axial direction of the Z-axis gradient coil, the greater a density of the continuous helical wrapping of the first coil or the second coil of the Z-axis gradient coil, as illustrated in FIG. 3.

As shown in FIG. 3, winding of coils of the Z-axis gradient coil are performed in such a way that densities of the coils that are successively wound along the axial direction are not the same. The density of the coils near the center of the Z-axis gradient coil is great, and the density of the coils far away from the center of the Z-axis gradient coil is low, so as to increase the current distribution area, thus making the inflection point of the Z-axis magnetic field strength far away from the origin.

In some embodiments of the present disclosure, by setting the density nearer to the center of the Z-axis gradient coil larger, the magnetic field variation in a near-center region can be enhanced, which makes the signals in the near-center region more sensitive and thus improves the imaging quality. Increasing the density nearer to the center of the Z-axis gradient coil can also effectively reduce signal attenuations with distance, and improve the imaging accuracy and contrast. Increasing the density near the center of the Z-axis gradient coil can also effectively reduce signal attenuations with distance, improve imaging accuracy and contrast, and at the same time, optimize the uniformity of the magnetic field, so that the consistency of the imaging effect obtained when scanning different parts of a scanning area is better, and avoid imaging distortions due to the non-uniformity of the magnetic field or other factors.

In some embodiments, as shown in FIG. 3, along the axial direction of the Z-axis gradient coil, the first coil comprises a first density segment 161 and a second density segment 162; the second coil comprises a third density segment 163 and a fourth density segment 164. A spacing of two adjacent coils in the first density segment 161 may be within a range of 2 mm-30 mm. A spacing of the two adjacent coils in the second density segment 162 may be within a range of 30 mm-70 mm. In some embodiments, the spacing of the two adjacent coils in the first density segment 161 may be spaced apart from 5 mm-25 mm. The spacing of the two adjacent coils in the second density segment 162 may be 35 mm-65 mm. In some embodiments, the spacing of the two adjacent coils in the first density segment 161 may be 10 mm-20 mm. The spacing of the two adjacent coils in the second density segment 162 may be 45 mm-60 mm. In some embodiments, the spacing of the two adjacent coils in the first density segment 161 may be 15 mm-20 mm; and the spacing of two adjacent coils in the second density segment 162 may be 45 mm-55 mm. A spacing of two adjacent windings in the third density segment 163 may be within a range of 2 mm-30 mm. A spacing of the two adjacent windings in the fourth density segment 164 may be within a range of 30 mm-70 mm. In some embodiments, the spacing of the two adjacent windings in the third density segment 163 may be spaced apart from 5 mm-25 mm. The spacing of the two adjacent windings in the fourth density segment 164 may be 35 mm-65 mm. In some embodiments, the spacing of the two adjacent windings in the third density segment 163 may be 10 mm-20 mm. The spacing of the two adjacent windings in the fourth density segment 164 may be 45 mm-60 mm. In some embodiments, the spacing of the two adjacent windings in the third density segment 163 may be 15 mm-20 mm; and the spacing of two adjacent windings in the fourth density segment 164 may be 45 mm-55 mm.

The first density segment 161 is a coil segment of the first coil near the center of the Z-axis gradient coil, where the coils are more tightly wound compared with a region far away from the center of the Z-axis gradient coils. The second density segment 162 is a coil segment of the first coil near an end of the Z-axis gradient coil, where the coils are more sparsely wound compared with the coil segment near the center of the Z-axis gradient coil. The third density segment 163 is a coil segment of the second coil near the center of the Z-axis gradient coil, where the coils are more tightly wound compared with a region far away from the center of the Z-axis gradient coils. The fourth density segment 164 is a coil segment of the second coil near an end of the Z-axis gradient coil, where the coils are more sparsely wound compared with the coil segment near the center of the Z-axis gradient coil.

In some embodiments, along the axial direction of the Z-axis gradient coil, the first coil and the second coil may also include a fifth density segment, a sixth density segment, or more. For example, the fifth density segment may be closer to the end of the Z-axis gradient coil than the second density segment, and the sixth density segment may be closer to the end of the Z-axis gradient coil than the fourth density segment, whereby the two adjacent coils in the fifth density segment may be spaced apart greater than that in the second density segment. A spacing of the two adjacent coils in the sixth density segment may be greater than that in the fourth density segment.

In some embodiments of the present disclosure, by setting the spacing of two adjacent coils in the first density segment and the second density segment, density variation of the Z-axis gradient coil can be arranged reasonably, and the imaging accuracy and imaging contrast can be improved, so that the imaging consistency is good.

In some embodiments, a ratio of a spacing of two adjacent windings in the first density segment 161 to a spacing of two adjacent windings in the second density segment 162 is within a range of 0.02-1.0. In some embodiments, the ratio of the spacing of two adjacent windings in the third density segment 163 to the spacing of two adjacent coils in the fourth density segment 164 is within a range of 0.02-1.0. In some embodiments, the ratio of spacing of two adjacent windings in the first density segment 161 to the spacing of two adjacent coils in the second density segment 162 is within a range of 0.05-0.5. In some embodiments, the ratio of the spacing of two adjacent windings in the third density segment 163 to the spacing of two adjacent windings in the fourth density segment 164 is within a range of 0.05-0.5. In some embodiments, the ratio of spacing of two adjacent windings in the first density segment 161 to the spacing of two adjacent windings in the second density segment 162 is within a range of 0.1-0.3. In some embodiments, the ratio of the spacing of two adjacent windings in the third density segment 163 to the spacing of two adjacent windings in the fourth density segment 164 is within a range of 0.1-0.3.

A length of the first density segment 161, a length of the second density segment 162, a length of the third density segment 163, and a length of the fourth density segment 164 (e.g., the lengths extending axially) may be determined according to demand. In some embodiments, a ratio of the length of the first density segment 161 to the length of the second density segment 162 is within a range of 0.3-1.5. In some embodiments, the ratio of the length of the first density segment 161 to the length of the second density segment 162 is within a range of 0.5-1.2. In some embodiments, the ratio of the length of the first density segment 161 to the second density segment 162 is within a range of 0.5-1.0. In some embodiments, a ratio of the length of the third density segment 163 to the length of the fourth density segment 164 is within a range of 0.3-1.5. In some embodiments, the ratio of the length of the third density segment 163 to the length of the fourth density segment 164 is within a range of 0.5-1.2. In some embodiments, the ratio of the length of the third density segment 163 to the fourth density segment 164 is within a range of 0.5-1.0.

In some embodiments of the present disclosure, by determining an appropriate density and a ration of lengths of different density segments, the current can be uniformly distributed in the conductor, thereby ensuring that a uniform gradient magnetic field is generated, improving the imaging quality and accuracy, and enhancing device stability.

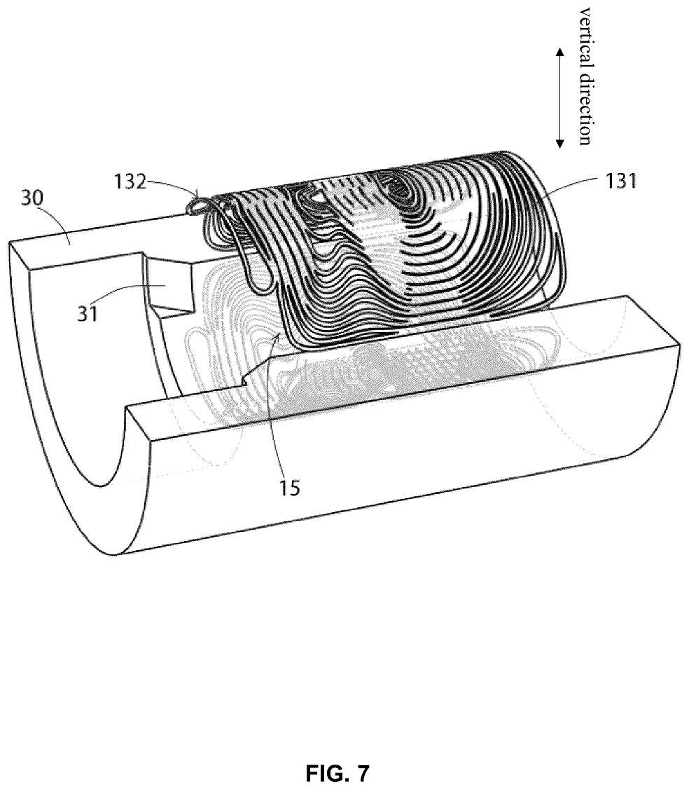

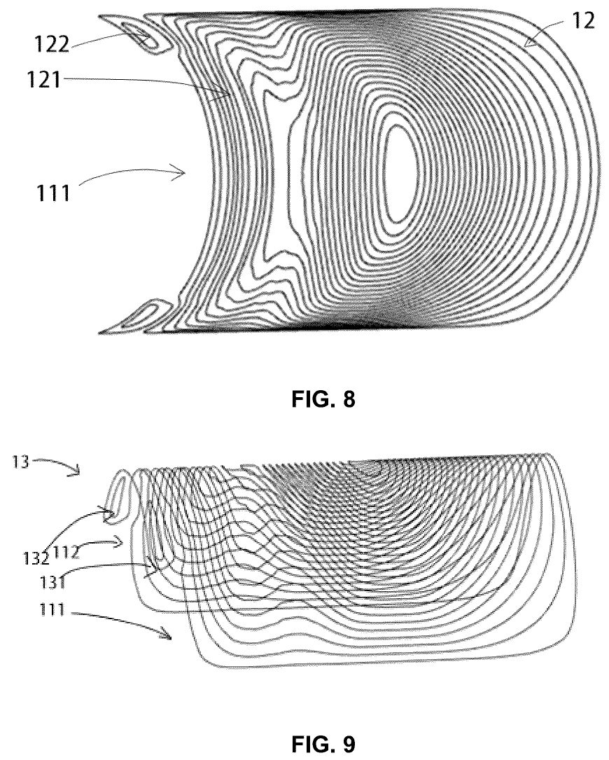

FIG. 6 is a schematic diagram of a portion of the structure of one of the embodiments of the gradient coil assembly according to some embodiments of the present disclosure; FIG. 7 is a schematic diagram of a portion of the structure of the gradient coil assembly according to some embodiments of the present disclosure; FIG. 8 is a schematic diagram of a structure of the X-axis coil according to some embodiments of the present disclosure; FIG. 9 is a schematic diagram of a structure of the Y-axis coil according to some embodiments of the present disclosure.

In some embodiments, as shown in FIG. 6-FIG. 9, the gradient coil assembly includes a main coil 10 and a shielding coil 20. The main coil 10 is formed by winding of conductors, and the main coil 10 is wrapped around to form a scanning space for the human body to enter into. The scanning space may be cylindrical in shape.

In some embodiments, the main coil 10 forms a gradient field and an end of the main coil 10 is recessed in an axial direction of the main coil 10 to form a refuge area 11. The refuge area 11 is configured to accommodate at least a portion of a shoulder of a human body. The shielding coil 20 is likewise disposed around and on an outer peripheral side of the main coil 10 for forming a gradient shielding field to shield eddy currents from the main coil 10 to a superconducting magnet. In this way, since the human shoulder of a human body can be accommodated in the refuge area 11, the human body may be moved further in the direction of the main coil 10 such that the entire head of the human body may be accommodated in the main coil 10. The main coil 10 is provided within the shielding coil 20 and has a diameter that is smaller than the shielding coil 20.

It is to be explained that the scanning space inside the main coil 10 is a space for scanning the head of the human body. The shielding coil 20 is provided on the outer peripheral side of the main coil 10. The length of the shielding coil 20 is greater than that of the main coil 10 in the axial direction. The shielding coil 20 is surrounded to form space including the scanning space as described above. The area within the space other than the scanning space is capable of generating a gradient magnetic field of normal strength.

In some embodiments, as shown in FIG. 8 and FIG. 9, a central axis of a first notch 111, a central axis of a second notch 112, and a central axis of the main coil 10 are located in the same plane, such that the first notch 111 and the second notch 112 are located on opposite sides of the main coil 10. That is, the first notch 111 and the second notch 112 are located in the middle of the main coil 10, so that the distance between the first notch 111 and the second notch 112 is great enough to be applied to a plurality of human bodies with different sizes, and the resulting two-side symmetrical structure is convenient for machining.

Exemplarily, in this embodiment, the first notch 111 and the second notch 112 are both rectangular structures. In other embodiments, the first notch 111 and the second notch 112 may also be irregular shapes such as a conical, a stepped shape, a curved shape, a semi-circular shape, a trapezoidal shape, or a combination of rectangular and semi-circular.

In some embodiments, the main coil 10 includes an X-axis gradient coil, a Y-axis gradient coil, and a Z-axis gradient coil disposed in layers. Referring to FIG. 8-FIG. 9, the main coil 10 includes at least an X-axis coil 12 and a Y-axis coil 13. Along the radial direction of the main coil 10, the X-axis coil 12 is disposed on a peripheral side of the Y-axis coil 13 or the Y-axis coil 13 is located on a peripheral side of the X-axis coil 12. For example, the X-axis coil 12 and the Y-axis coil 13 are located at different layers in a radial direction of a cylindrical structure formed by the main coil 10. As shown in FIG. 8, the X-axis coil 12 is an X-axis gradient coil for generating an X-direction gradient field, and as shown in FIG. 9, the Y-axis coil 13 is a Y-axis gradient coil for generating a Y-direction gradient field.

In some embodiments, both the X-axis coil 12 and the Y-axis coil 13 are provided in a multi-layer configuration. The same type of the X-axis coil 12 of different layers are connected in series, and the same type of the Y-axis coil 13 of different layers are connected in series.

In some embodiments, along the radial direction of the main coil 10, the X-axis coil 12 and the Y-axis coil 13 are arranged sequentially. For example, from the inside to the outside, the X-axis coil 12, the Y-axis coil 13, the X-axis coil 12, and the Y-axis coil 13 are arranged. Of course, in other embodiments, the positions of the X-axis coil 12 and the Y-axis coil 13 may be interchanged.

In some embodiments, one of the X-axis coil 12 and the Y-axis coil 13 comprises a first body segment and a first extension segment disposed in series. The first extension segment is disposed at an end of the first body segment. For example, as shown in FIG. 9, the Y-axis coil 13 comprises a first body segment 131 and a first extension segment 132. The first extension segment 132 is disposed at an end portion of the first body segment 131 and centrally disposed with respect to the first body segment 131. A refuge area 11 is formed between the first extension segments 132 of each of the two Y-axis coils 13. In some embodiments, the other of the X-axis coil 12 and the Y-axis coil 13 comprises a second body segment and two second extension segments disposed in series. Both the second extension segments are disposed at an end of the second body segment and spaced apart along a circumferential direction of the main coil 10. The two second extensions segments may also be provided at the two ends of the Z-axis gradient coil along the axial direction. For example, as shown in FIG. 8, the X-axis coil 12 includes a second body segment 121 and two second extension segments 122. The two second extension segments 122 are disposed at an end portion of the second body segment 121 and spaced apart. A refuge area 11 is formed between adjacent second extension segments 122.

In some embodiments, the gradient coil assembly includes two sets of the X-axis coils 12 and two sets of the Y-axis coils 13. In some embodiments, a refuge area 11 is formed between two adjacent first extension segment of one of the two sets of the X-axis coils 12 and two sets of the Y-axis coils 13. For example, as shown in FIG. 9, the refuge area 11 is formed between the first extension segment 132 of each of the two sets of the Y-axis coils 13. In some embodiments, a refuge area is formed between two adjacent second extension segments in each set of the other one of the two sets of the X-axis coils 12 and the two sets of the Y-axis coils 13. For example, the refuge area 11 is formed between adjacent second extension segments 122 in one set of the X-axis coils 12, as shown in FIG. 8. The refuge area 11 is configured to accommodate at least a portion of a human body (e.g., at least a portion of a shoulder of the human body).

In this way, both the first body segment 131 (or the second body segment 121) and the first extension segment 132 (or the second extension segment 122) are capable of emitting a gradient magnetic field, and the first extension segment 132 (or the second extension segment 122) is located at the end portion of the first body segment 131 (or the second body segment 121), which is capable of complementing the strength of the gradient magnetic field at the end portion of the first body segment 131 (or the second body segment 121). Since the refuge area 11 is located between two adjacent first extension segments 132 (or two adjacent second extension segments 122), that is to say, an arrangement of wires in the first extension segment 132 (or the second extension segment 122) is an arrangement of wires at the edge of the refuge area 11, thereby reinforcing the strength of the gradient magnetic field at the edge of the refuge area 11 and thereby enhancing an overall strength of the main coil 10.

In some embodiments, the first extension segment 132 is disposed at the end of the first body segment 131 and is centrally disposed so as to form a convex end structure. The end of the second body segment 121 is disposed with two spaced apart second extension segments 122 so as to form a concave zigzag structure, and the convex end structure and the concave zigzag structure are staggered in the radial direction, such that the refuge areas 11 formed between the adjacent first extension segments 132 (or the adjacent second extension segments 122) overlap in the radial direction.

In some embodiments, the refuge area 11 includes a first notch 111 and a second notch 112. The first notch 111 and the second notch 112 are located on opposing sides in the radial direction of the main coil 10 (e.g., on the same end of the gradient coil assembly). In this way, a human body is able to enter the scanning space along the mid-axis position of the main coil 10, and both sides of the shoulders of the human body are able to be accommodated in the first notch 111 and the second notch 112 so that the head of the human body is able to be centered in the scanning space.

In some embodiments, notched gradient coils formed by the main coils 10 having the refuge areas 11, where current density is forcibly assigned a value of 0 in the notched refuge areas 11, result in current densities that would otherwise be in the notched refuge areas 11 to be squeezed into notched outer circumferential regions, causing the current density in these circumferential regions to increase, and when the current density increases enough, a wire distribution will be formed in the circumferential regions outside of these notches.

It will be appreciated that the refuge area 11 may also have only one of the first notch 111 and the second notch 112. Alternatively, the first notch 111 and the second notch 112 are located on the same side in the radial direction of the main coil 10, thereby targeting different parts of the human body or different postures of the human body. The purpose of the refuge area 11 is to accommodate the parts of the human body that will interfere with the main coil 10, thereby facilitating the entry of the parts of the human body to be scanned into the scanning space, and thus is not limited to the above described accommodating the shoulders on both sides of the human body, so that the head of the human body is centered.

According to some embodiments of the present disclosure, the gradient coil assembly includes two sets of the X-axis coils 12. The two sets of the X-axis coils 12 are disposed opposite to each other in a horizontal direction. According to some embodiments of the present disclosure, the gradient coil assembly includes two sets of the Y-axis coils 13. The two sets of the Y-axis coils 13 are disposed opposite to each other along a vertical direction. In this way, each of the two sets of the X-axis coils 12 is formed by conductor winding, and then assembled together, which is a less difficult machining process as compared to the direct molding approach. The Y-axis coil 13 is divided into two groups and set relative to each other with the same technical effect, and will not be repeated here.

According to some embodiments of the present disclosure, the two sets of the Y-axis coils 13 are disposed on outer peripheral sides of the two sets of the X-axis coils 12, the end portions of each of the two sets of the X-axis coils 12 have two second extension segments 122, and along the circumferential direction of the main coils 10, a first refuge space 14 is formed between the two second extension segments 122. A middle position of the end portion of each group of the Y-axis coils 13 has a first extension segment 132. A second refuge space 15 is formed between the first extension segments 132 on two adjacent groups of the Y-axis coils 13, and the first refuge space 14 and the second refuge space 15 are provided in an overlapping manner along the radial direction of the main coil 10.

Exemplarily, a diameter of the X-axis coil 12 is 480 mm and a diameter of the Y-axis coil 13 is 490 mm to accommodate common human body sizes to be detected.

In another embodiment, the positions of the X-axis coil 12 and the Y-axis coil 13 can be interchangeable. Alternatively, the X-axis coil 12 is provided with a centered first extension segment, and the Y-axis coil 13 is provided with two spaced-apart second extension segments, both capable of forming the refuge area 11.

According to some embodiments of the present disclosure, in the X-axis coil 12 and the Y-axis coil 13, there can be only one refuge space. For example, only one of the X-axis coil 12 and the Y-axis coil 13 includes an extension segment and the other includes only the main body segment, which is also able to form the refuge area 11 of the technical effect.

In some embodiments of the present disclosure, by arranging only one of the X-axis coil or the Y-axis coil to form the refuge area while the other coil does not form the refuge area, the design can be adjusted according to the different parts of the human body or the different postures. In order to adapt to the specific scanning needs, designers can optimize the structure of the gradient coil assembly according to the actual application scenarios and human body characteristics, thus improving scanning convenience and imaging quality.

According to some embodiments of the present disclosure, the X-axis coil 12 and/or the Y-axis coil 13 can be formed into a single-layer structure by winding a single-layer conductor. The X-axis coil 12 and the Y-axis coil 13 formed by winding a single layer of conductor has a small thickness and takes up less space, and therefore. With the same amount of space, compares to the formation of the X-axis coil 12 and the Y-axis coil 13 through two layers of conductors that cooperate from the top and bottom, this type of winding is able to set up more layers of the X-axis coil 12 and the Y-axis coil 13, the strength of the gradient magnetic field is stronger, and the imaging quality is higher.

According to some embodiments of the present disclosure, a density of continuous helical wrapping of the first body segment 131 is greater than a density of continuous helical wrapping of the first extension segment 132. A density of continuous helical wrapping of the second body segment 121 is greater than a density of continuous helical wrapping of the second extension segment 122.

According to some embodiments of the present disclosure, a reasonable refuge space can be ensured by making that the densities of the continuous helical wrapping of the first extension segment and the second extension segment is smaller in comparison to the densities of the body segments corresponding thereto. The smaller densities may make the current distribution in the extension segment uniform, thereby improving the overall imaging quality and the uniformity of the gradient field, and avoiding generating a too high current density at a specific location. The generation of localized heat and electromagnetic interference is reduced. And allows designers to flexibly adjust to different scanning needs and different human body characteristics to suit different application scenarios. At the same time, it can also simplify the process of manufacturing and arranging the coils, and reduce the production cost and technical difficulty.

In some embodiments, a cooling device can be provided around the first extension segment and the second extension segment to balance a temperatures generated during an operation of the gradient coil assembly, to enhance the effectiveness of the use of the gradient coil assembly, and to prolong the service life of the gradient coil assembly.

According to some embodiments of the present disclosure, the gradient coil assembly may include cooling tubes, which can be disposed along the edge of the refuge area 11. The cooling tubes have a cooling medium flowing through the cooling tubes. The cooling medium may absorb heat to the gradient coil assembly to cool the gradient coil assembly, thereby enhancing the stability of the operation of the gradient coil assembly as well as human comfort.

According to some embodiments of the present disclosure, the X-axis coil and the Y-axis coil are able to form a dedicated space for accommodating the head to satisfy the requirement of high-precision imaging of the head for the homogeneity of the gradient field, and at the same time, the refuge area is formed to avoid the shoulders of the human body, so that the head of the human body can enter the scanning space completely.

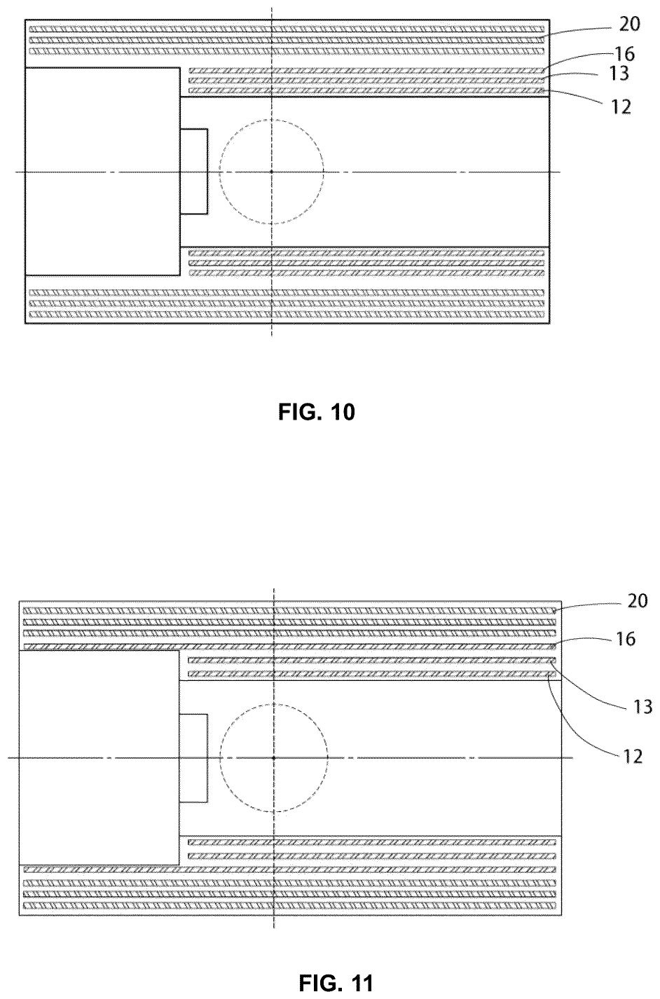

FIG. 10 is a cross-sectional view of a magnetic resonance apparatus according to some embodiments of the present disclosure. FIG. 11 is a cross-sectional view of a magnetic resonance apparatus according to some embodiments of the present disclosure.

Some embodiments of the present disclosure provide a magnetic resonance imaging system comprising the aforementioned gradient coil assembly for generating a gradient magnetic field. The aforementioned gradient coil assembly may also be used in multimodal systems formed by a positron emission computed tomography (PET) device and a magnetic resonance imaging devices, a magnetic resonance radiation therapy system (MR-RT), and the like.

In some embodiments, the magnetic resonance imaging system includes a gradient coil assembly as shown in FIG. 10 and FIG. 11, the gradient coil assembly including an X-axis coil 12, a Y-axis coil 13, and a Z-axis gradient coil 16. The Z-axis gradient coil 16 includes a first coil and a second coil. The first coil and the second coil are arranged along an axial direction of the Z-axis gradient coil 16. The first coil comprises a first subcoil and a second subcoil. The first subcoil and the second subcoil extend alongside each other. the second coil comprises a third subcoil and a fourth subcoil. The third subcoil and the fourth subcoil extend alongside each other. The third subcoil is connected in series with the first subcoil to form a first spiral winding, the fourth subcoil is connected in series with the second subcoil to form a second spiral winding. The first spiral winding is connected in parallel with the second spiral winding.

For more information about the X-axis coil, the Y-axis coil, and the Z-axis gradient coil, see FIGS. 1-10 and the descriptions thereof.

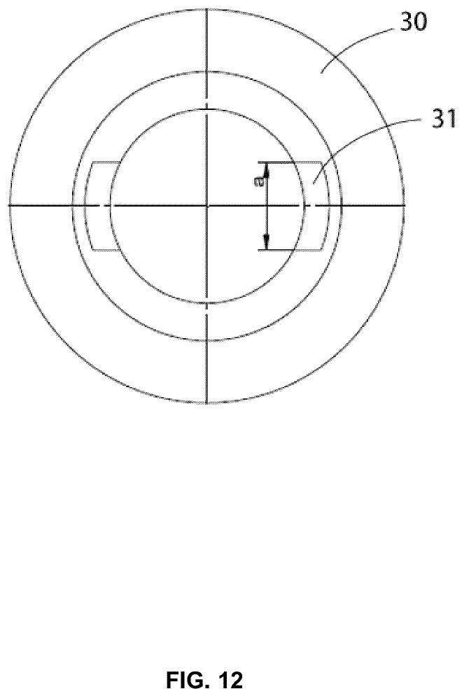

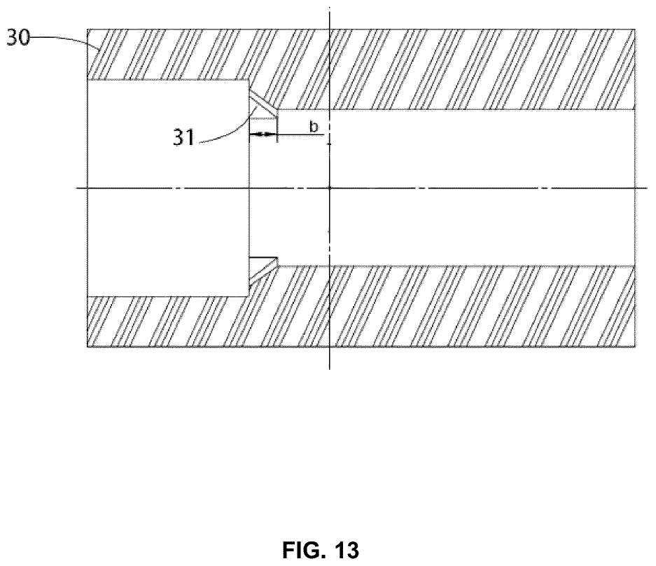

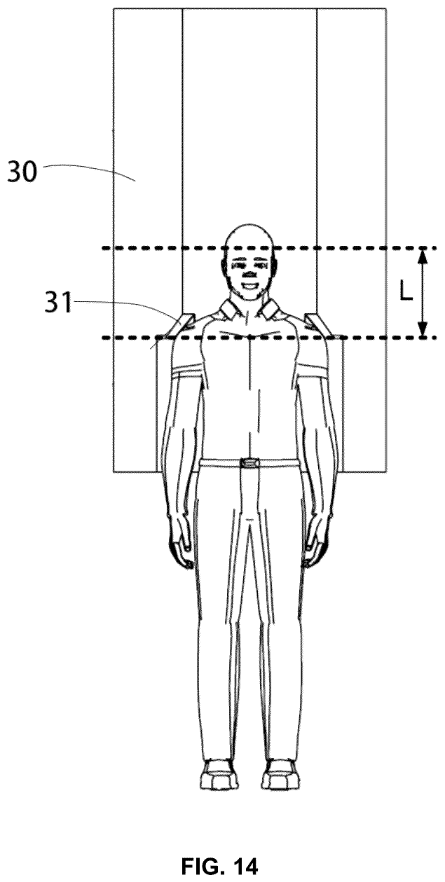

FIG. 12 is a cross-sectional view of a gradient coil assembly according to some embodiments of the present disclosure. FIG. 13 is another angled cross-sectional view of a gradient coil assembly according to some embodiments of the present disclosure. FIG. 14 is a schematic diagram of a magnetic resonance apparatus according to some embodiments shown in the present disclosure.

According to some embodiments of the present disclosure, as shown in FIG. 12-FIG. 14, the magnetic resonance imaging system further comprises a body 30 with an avoidance slot 31. At least a portion of the refuge area 11 overlaps the avoidance slot 31.

In some embodiments, the body 30 has a chamber within the body 30, and the avoidance slots 31 are provided on opposite sides of a wall within the chamber and are located on a horizontal plane where the axis of the chamber is located. When the body 30 is applied to the magnetic resonance imaging system and is placed horizontally (e.g., an axis of the body 30 is parallel to the ground) on the ground, a slot height of the avoidance slot 31 in the vertical direction is a. The slot height a satisfies 100 mm<a<350 mm. A slot depth of the a voidance slot 31 in the horizontal direction is b. The slot depth b satisfies 30 mm<b<200 mm. In this way, dimensions of the avoidance slots 31 are reasonably set so as to be adapted to a wide range of body shapes to be detected. Due to the presence of the avoidance slot 31, the human body is able to move closer to a scan center of the main coil 10 (e.g., a distance L in FIG. 14 is short).

According to some embodiments of the present disclosure, a user is able to conveniently place a target to be scanned at a specified location by providing the refuge area on the gradient coil assembly that can avoid the human body. The first extension segment and the second extension segment are provided on the main body segment of the gradient coil assembly, the first extension segment and the second extension segment are able to reinforce the strength of the gradient magnetic field around the refuge area of the gradient coil assembly to ensure the imaging quality. The first coil and the second coil are formed by winding a single layer of conductor, less space is occupied, so that multiple layers can be deployed in a limited space, and superposition of the gradient magnetic field of multiple layers is intense, so that the imaging quality is good.

The technical effects of the embodiments of the present disclosure are further illustrated below in connection with examples.

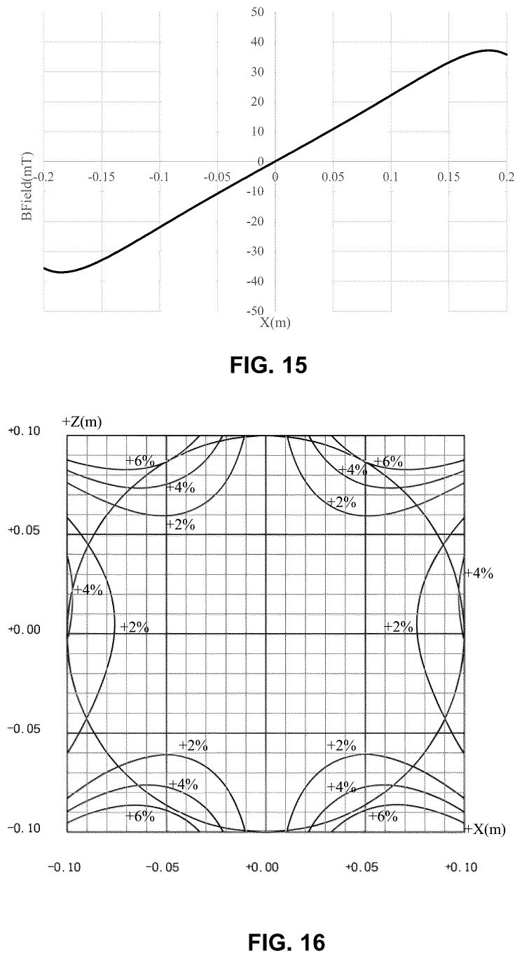

FIG. 15 is a schematic diagram of a distribution of a magnetic field created by an X-axis coil according to some embodiments of the present disclosure. In FIG. 15, the horizontal coordinate is the X-coordinate position in meters, and the vertical coordinate indicates the flux density of the magnetic field (in mT) generated under the corresponding coordinate position. As shown in FIG. 15, a maximum current of the X-axis coil is 1000 A, a maximum voltage is 2000 V, a maximum gradient strength is 213 mT/m, and a maximum climb rate is 680 mT/m/ms. From FIG. 15, it can be seen that the flux density of the magnetic field satisfies a good linear relationship within the X coordinate positions from −0.1 m to 0.1 m X.

FIG. 16 is a linearity distribution of an X-axis coil on an XZ plane according to some embodiments of the present disclosure. In FIG. 16, the horizontal coordinate is the X coordinate position, and the vertical coordinate indicates the Z coordinate position. The circle in FIG. 16 is an ideal target imaging region, and the curves in FIG. 16 indicate deviations from an ideal flux density of the magnetic field. From FIG. 16, it can be seen that the flux density of the magnetic field satisfies good linearity in the large part of the target imaging region, and only the edge region has a deviation within a range of 2%-4%.

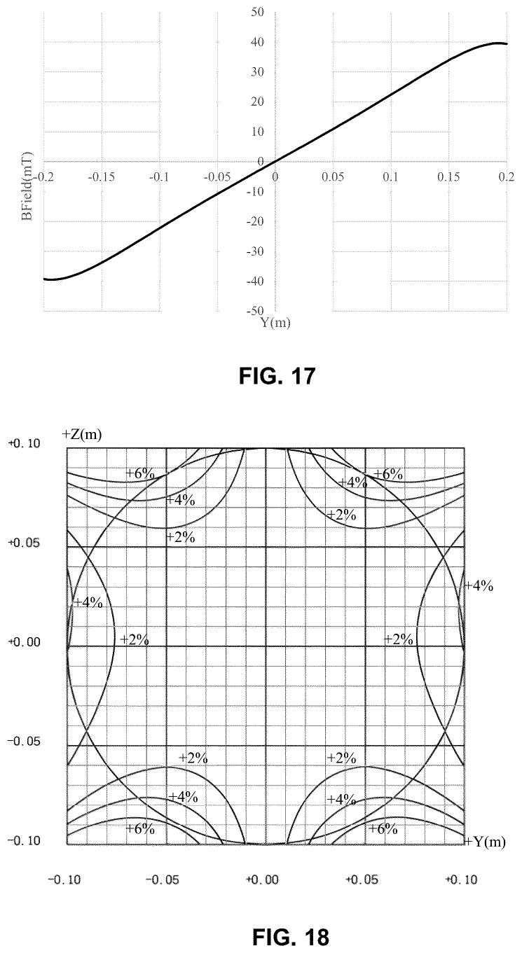

FIG. 17 is a schematic diagram of a distribution of a magnetic field formed by a Y-axis coil according to some embodiments of the present disclosure. The horizontal coordinate is the Y coordinate position in meters; and the vertical coordinate indicates the flux density of the magnetic field (in mT) generated under the corresponding coordinate position. As shown in FIG. 17, a maximum current of the Y-axis coil is 1000 A, a maximum voltage is 2000 V, a maximum gradient strength is 214 mT/m, and a maximum climb rate is 663 mT/m/ms. From FIG. 17, it can be seen that the flux density of the magnetic field satisfies a good linear relationship within the Y coordinate positions from −0.1 m to 0.1 m.

FIG. 18 is a linearity distribution of a Y-axis coil on a YZ plane according to some embodiments of the present disclosure. In FIG. 18, the horizontal coordinate is the Y coordinate position, and the vertical coordinate indicates the Z coordinate position. A circle in FIG. 18 is an ideal target imaging region, and curves in FIG. 18 indicate deviations from an ideal flux density of the magnetic field. From FIG. 18, it can be seen that the flux density of the magnetic field satisfies good linearity in the large part of the target imaging region, and only the edge region has a deviation within a range of 2%-4%.

The basic concepts have been described above, and it is apparent to those skilled in the art that the foregoing detailed disclosure is intended as an example only and does not constitute a limitation of the present disclosure. While not expressly stated herein, a person skilled in the art may make various modifications, improvements, and amendments to the present disclosure. Those types of modifications, improvements, and amendments are suggested in the present disclosure, so those types of modifications, improvements, and amendments remain within the spirit and scope of the exemplary embodiments of the present disclosure.

Also, the specification uses specific words to describe embodiments of the specification. Such as “an embodiment”, “an embodiment”, and/or “some embodiments” means a feature, structure, or characteristic associated with at least one embodiment of the present disclosure. Accordingly, it should be emphasized and noted that “one embodiment” or “an embodiment” or “an alternative embodiment” in different places in the present disclosure do not necessarily refer to the same embodiment. In addition, certain features, structures, or characteristics of one or more embodiments of the present disclosure may be suitably combined.

Similarly, it should be noted that in order to simplify the presentation of the disclosure of the present disclosure, and thereby aid in the understanding of one or more embodiments of the invention, the foregoing descriptions of embodiments of the present disclosure sometimes group multiple features together in a single embodiment, accompanying drawings, or a description thereof. However, this method of disclosure does not imply that the objects of the present disclosure require more features than those mentioned in the claims. Rather, claimed subject matter may lie in less than all features of a single foregoing disclosed embodiment.

Some embodiments use numbers to describe the number of components, attributes, and it should be understood that such numbers used in the description of the embodiments are modified in some examples by the modifiers “about”, “approximately”, or “substantially”. Unless otherwise noted, the terms “about,” “approximately,” or “approximately” indicate that a ±20% variation in the stated number is allowed. Correspondingly, in some embodiments, the numerical parameters used in the specification and claims are approximations, which approximations are subject to change depending on the desired characteristics of individual embodiments. In some embodiments, the numerical parameters should take into account the specified number of valid digits and utilize a general digit retention method. While the numerical domains and parameters used to confirm the breadth of their ranges in some embodiments of the present disclosure are approximations, in specific embodiments such values are set to be as precise as possible within a feasible range.

For each of the patents, patent applications, patent application disclosures, and other materials cited in the present disclosure, such as articles, books, specification sheets, publications, documents, and the like, these are hereby incorporated by reference in their entirety into the present disclosure. Application history documents that are inconsistent with or conflict with the contents of the present disclosure are excluded, as are documents (currently or hereafter appended to the present disclosure) that limit the broadest scope of the claims of the present disclosure. It should be noted that to the extent that there is an inconsistency or conflict between the descriptions, definitions, and/or use of terms in the materials appurtenant to the present disclosure and those set forth herein, the descriptions, definitions and/or use of terms in the present disclosure shall prevail.

Finally, it should be understood that the embodiments described in the present disclosure are only used to illustrate the principles of the embodiments of the present disclosure. Other deformations may also fall within the scope of the present disclosure. As such, alternative configurations of embodiments of the present disclosure may be viewed as consistent with the teachings of the present disclosure as an example, not as a limitation. Correspondingly, the embodiments of the present disclosure are not limited to the embodiments expressly presented and described herein.

What is claimed is:

1. A gradient coil assembly comprises a Z-axis gradient coil, the Z-axis gradient coil comprising a first coil and a second coil, the first coil and the second coil being arranged along an axial direction of the Z-axis gradient coil, wherein:
the first coil comprises a first subcoil and a second subcoil, the first subcoil and the second subcoil extend alongside each other;
the second coil comprises a third subcoil and a fourth subcoil, the third subcoil and the fourth subcoil extend alongside each other;
the third subcoil is connected in series with the first subcoil to be supplied with a first current, the fourth subcoil is connected in series with the second subcoil to be supplied with a second current.

2. The gradient coil assembly according to claim 1, wherein the first subcoil is connected to the second subcoil at an end of the Z-axis gradient coil; and the third subcoil is connected to the fourth subcoil at another end of the Z-axis gradient coil.

3. The gradient coil assembly according to claim 1, wherein the first subcoil is connected to the third subcoil near a center of the Z-axis gradient coil; the second subcoil is connected to the fourth subcoil near the center of the Z-axis gradient coil.

4. The gradient coil assembly according to claim 1, wherein winding trajectories of the first subcoil and the fourth subcoil are centrally symmetric about a center of the Z-axis gradient coil; and winding trajectories of the second subcoil and the third subcoil are centrally symmetric about the center of the Z-axis gradient coil.

5. The gradient coil assembly according to claim 1, wherein along the axial direction of the Z-axis gradient coil, the first coil has different densities of continuous helical wrapping and the second coil has different densities of continuous helical wrapping.

6. The gradient coil assembly according to claim 1, wherein along the axial direction of the Z-axis gradient coil, the closer to a center of the Z-axis gradient coil, the greater a density of continuous helical wrapping of the first coil or the second coil of the Z-axis gradient coil.

7. The gradient coil assembly according to claim 6, wherein along the axial direction of the Z-axis gradient coil, the first coil comprises a first density segment and a second density segment; the second coil comprises a third density segment and a fourth density segment.

8. The gradient coil assembly according to claim 7, wherein a ratio of a spacing of two adjacent windings in the first density segment to a spacing of two adjacent windings in the second density segment is within a range of 0.02-1.0, or a ratio of the spacing of two adjacent windings in the third density segment to the spacing of two adjacent windings in the fourth density segment is within a range of 0.02-1.0.

9. The gradient coil assembly according to claim 7, wherein a ratio of a length of the first density segment to a length of the second density segment is within a range of 0.3-1.5, or a ratio of a length of the third density segment to a length of the fourth density segment is within a range of 0.3-1.5.

10. The gradient coil assembly according to claim 1, wherein the gradient coil assembly comprises a main coil and a shielding coil, the shielding coil being arranged around the outside, in a radial direction, of the main coil; the Z-axis gradient coil being the main coil.

11. The gradient coil assembly according to claim 10, wherein the main coil surrounds to form a space accommodating at least a portion of a human body, an end of the main coil being recessed to form a refuge area in the axial direction of the main coil, and the refuge area being capable of accommodating at least a portion of a shoulder of the human body.

12. The gradient coil assembly according to claim 11, wherein the main coil comprises an X-axis coil and a Y-axis coil; the Y-axis coil comprises a first body segment and a first extension segment, the first extension segment being disposed at an end portion of the first body segment; and/or the X-axis coil comprises a second body segment and two second extension segments, and both the two second extension segments being disposed at an end portion of the second body segment.

13. The gradient coil assembly according to claim 12, wherein the gradient coil assembly comprises two sets of X-axis coils and two sets of Y-axis coils; a refuge area being formed between two first extension segments of the two sets of Y-axis coils, and/or, a refuge area being formed between two second extension segments of each of the two sets of X-axis coils, the refuge area being capable of accommodating at least a portion of a human body.

14. The gradient coil assembly according to claim 13, wherein the refuge area comprises a first notch and a second notch, the first notch and the second notch being disposed on opposing sides of the main coil in a radial direction of the main coil, respectively.

15. The gradient coil assembly according to claim 12, the gradient coil assembly comprises two sets of X-axis coils, the two sets of X-axis coils being disposed relative to each other along a horizontal direction; and/or, the gradient coil assembly comprises two sets of Y-axis coils, the two sets of Y-axis coils being disposed relative to each other along a vertical direction.

16. The gradient coil assembly according to claim 15, wherein the two sets of Y-axis coils are located on a peripheral side of the two sets of X-axis coils, an end of each set of the two sets of X-axis coils includes the two second extension segments, and a first refuge area is formed between the two second extension segments along the circumferential direction of the main coil, a middle of an end of each set of the two sets of Y-axis coils includes the first extension segment, and a second refuge area is formed between two first extension segments of the two adjacent sets of Y-axis coils in the adjacent space, the first refuge area and the second refuge area being provided coincidentally along the radial direction of the main coil.

17. The gradient coil assembly according to claim 12, wherein a density of continuous helical wrapping of the first body segment is greater than a density of continuous helical wrapping of the first extension segment, and a density of continuous helical wrapping of the second body segment is greater than a density of continuous helical wrapping of each of the two second extension segments.

18. The gradient coil assembly according to claim 10, wherein the main coil comprises X-axis coils and Y-axis coils; the X-axis coils and the Y-axis coils being provided in multiple layers, the X-axis coils of different layers being connected in series, and the Y-axis coils of different layers being connected in series.

19. A magnetic resonance imaging system comprises a gradient coil assembly, the gradient coil assembly comprising a Z-axis gradient coil, the Z-axis gradient coil comprising a first coil and a second coil, the first coil and the second coil being arranged along an axial direction of the Z-axis gradient coil, wherein:
the first coil comprises a first subcoil and a second subcoil, the first subcoil and the second subcoil extend alongside each other;
the second coil comprises a third subcoil and a fourth subcoil, the third subcoil and the fourth subcoil extend alongside each other;
the third subcoil is connected in series with the first subcoil to be supplied with a first current, the fourth subcoil is connected in series with the second subcoil to be supplied with a second current.

20. The magnetic resonance imaging system according to claim 19, wherein the gradient coil assembly comprises a main coil and a shielding coil, the shielding coil being arranged around the outside, in a radial direction, of the main coil; the Z-axis gradient coil being the main coil.
